(19) United States
(12) Patent Application Publication
(10) Pub. No.: US 2026/0129869 A1
(43) Pub. Date: May 7, 2026

(54) ELECTRONIC CHIP COMPRISING A MEMORY CIRCUIT

(71) Applicant: STMicroelectronics International N.V., Geneva (CH)

(72) Inventors: Andrea REDAELLI, Milano (IT); Roberto ANNUNZIATA, Monza (IT)

(73) Assignee: STMicroelectronics International N.V., Geneva (CH)

(21) Appl. No.: 19/381,094

(22) Filed: Nov. 6, 2025

(30) Foreign Application Priority Data
Nov. 7, 2024 (FR) FR2412187

(51) Int. Cl. H10B 63/00

(52) U.S. Cl. CPC H10B 63/24

(57) ABSTRACT

A memory circuit of a chip includes: an interconnection stack and several memory cells, each including a memory element above the stack and a selection transistor formed in the substrate and including a first node. Each element includes a first electrode, a layer form by an OTS material, and a second electrode connected to the layer on opposite side with respect to the first electrode. In each cell, the first node of the transistor is connected to the element via a conductive via extending through an entire thickness of the stack. The memory circuit further includes a control circuit configured to apply, between the first and the second electrodes of each element, first or second voltage impulses of respectively first or second opposite polarities to set respectively first or second logic states of the element.

### PRIORITY CLAIM

This application claims the priority benefit of French Application for Patent No. FR2412187, filed on November 7, 2024, the content of which is hereby incorporated by reference in its entirety to the maximum extent allowable by law.

### TECHNICAL FIELD

The present description relates generally to electronic chips and, in particular, to electronic chips comprising a memory circuit based on an ovonic threshold switching (OTS) material.

### BACKGROUND

Electronic chips include both memory circuits and logic circuits. More particularly of interest are electronic chips comprising memory circuits, including memory elements arranged in array, each memory element being associated to one or more selecting transistors. This transistor is used to separately program, erase, or read each memory element.

An ovonic threshold switching (OTS) material toggles between an "on" and "off" state depending on the amount of voltage potential applied across the electronic cell. The state of the ovonic threshold switch changes when a voltage through the ovonic threshold switch exceeds a threshold voltage. Once the threshold voltage is reached, the "on" state is triggered and the ovonic threshold switch is in a substantially conductive state. If the current or voltage potential drops below the threshold value, the ovonic threshold switch returns to the "off" state.

It would be desirable to improve at least in part some aspects of the known electronic chips.

### SUMMARY

In an embodiment, an electronic chip includes a memory circuit comprising: a semiconductor substrate; an interconnection stack arranged on the semiconductor substrate; and a plurality of memory cells, each memory cell comprising a memory element arranged above the interconnection stack and a selection transistor comprising a first conduction node and formed in the semiconductor substrate; wherein each memory element comprises a first electrode, an intermediate layer comprising an ovonic threshold switching material, and a second electrode connected to the intermediate layer on opposite side with respect to the first electrode; wherein, in each memory cell, the first conduction node of the selection transistor is connected to the memory element via a respective conductive via extending through an entire thickness of the interconnection stack; and wherein the memory circuit further comprises a control circuit structured and configured to apply, between the first electrode and the second electrode of each memory element, a first voltage impulse of a first polarity to set a first logic state of the memory element and a second voltage impulse of a second polarity, opposite the first polarity, to set a second logic state of the memory element.

According to an embodiment, the intermediate layer is made of a chalcogenide material and the second electrode comprises a resistor electrically contacting the intermediate layer.

According to an embodiment, the memory cells are organized in an array of bit lines and word lines and each memory cell is connected to a respective bit line by its first electrode and to a respective word line by its second electrode.

According to an embodiment, each transistor comprises a gate which is connected to a respective word line, and a second conduction node connected to the ground.

According to an embodiment, the memory cells is free of any phase change material.

According to an embodiment, the conductive via is made of a metallic material.

According to an embodiment, the interconnection stack has a thickness in the range from 100 nm to 600 nm.

According to an embodiment, the interconnection stack comprises a plurality of levels, each level comprising a first insulating layer and a second insulating layer, the first insulating layer is made of a material selected from the group consisting of: SiOC, porous SiOC, SiOCH, or porous SiOCH, and has a thickness in the range from 30 nm to 110 nm, and the second insulating layer is made of a material selected from the group consisting of: silicon carbonitride, silicon nitride, SiCH, SiNHC, or porous SiCN and has a thickness in the range from 2 nm to 50 nm.

According to an embodiment, the electronic chip comprises: a third insulating layer interposed between the interconnection stack and the memory element, the third insulating layer being made of a material selected from the group consisting of: silicon carbonitride, silicon nitride, SiCH, SiNHC, or porous SiCN and having a thickness in the range from 2 nm to 50 nm; and a fourth insulating layer interposed between the third insulating layer and the memory element, the fourth insulating layer being made of SiO₂, and having a thickness in the range from 10 nm to 50 nm.

According to an embodiment, for each memory element, the respective conductive via is in single piece.

According to an embodiment, the electronic chip comprises: an additional insulating layer interposed between the semiconductor substrate and the interconnection stack, and, for each memory element, a respective further via extending through an entire thickness of the additional insulating layer and directly connecting the selection transistor to the respective conductive via.

According to an embodiment, the conductive via is directly connected to the second electrode of the memory element.

Another embodiment provides a method of manufacturing an electronic chip comprising a memory circuit, comprising the following successive steps: a) forming fin field-effect selection transistors, comprising a first conduction node, in a semiconductor substrate; b) forming an interconnection stack arranged on the semiconductor substrate; and c) forming a plurality of memory elements arranged above the interconnection stack, each memory element comprising a first electrode, an intermediate layer comprising an ovonic threshold switching material, and a second electrode connected to the intermediate layer on opposite side with respect to the first electrode; wherein the first conduction node of the selection transistor of each memory cell is connected to the memory element via a respective conductive via extending through an entire thickness of the interconnection stack; the method further comprising a step of forming a control circuit structured and configured to apply, between the first electrode and the second electrode of each memory element, a first voltage impulse of a first polarity to set a first logic state of the memory element and a second voltage impulse of a second polarity, opposite the first polarity, to set a second logic state of the memory element.

According to an embodiment, the conductive via is formed between steps b) and c).

According to an embodiment, the step of forming of the conductive vias comprises a step of etching of the interconnection stack so as to form openings and a step of filling of said openings.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1A is a schematic and partial view of an example electronic chip including several memory cells of the ovonic threshold switching type;

FIG. 1B is another schematic and partial view of the chip illustrated in FIG. 1A;

FIG. 2 illustrates a voltage-current characteristic of the memory cell of FIGS. 1A and 1B; and

FIG. 3 illustrates a simplified schematic view of a memory circuit.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms "front", "back", "top", "bottom", "left", "right", etc., or to relative positional qualifiers, such as the terms "above", "below", "higher", "lower", etc., or to qualifiers of orientation, such as "horizontal", "vertical", etc., reference is made to the orientation shown in the figures.

Unless specified otherwise, the expressions "around", "approximately", “substantially” and "in the order of" signify within 10 % or 10°, and preferably within 5 % or 5°.

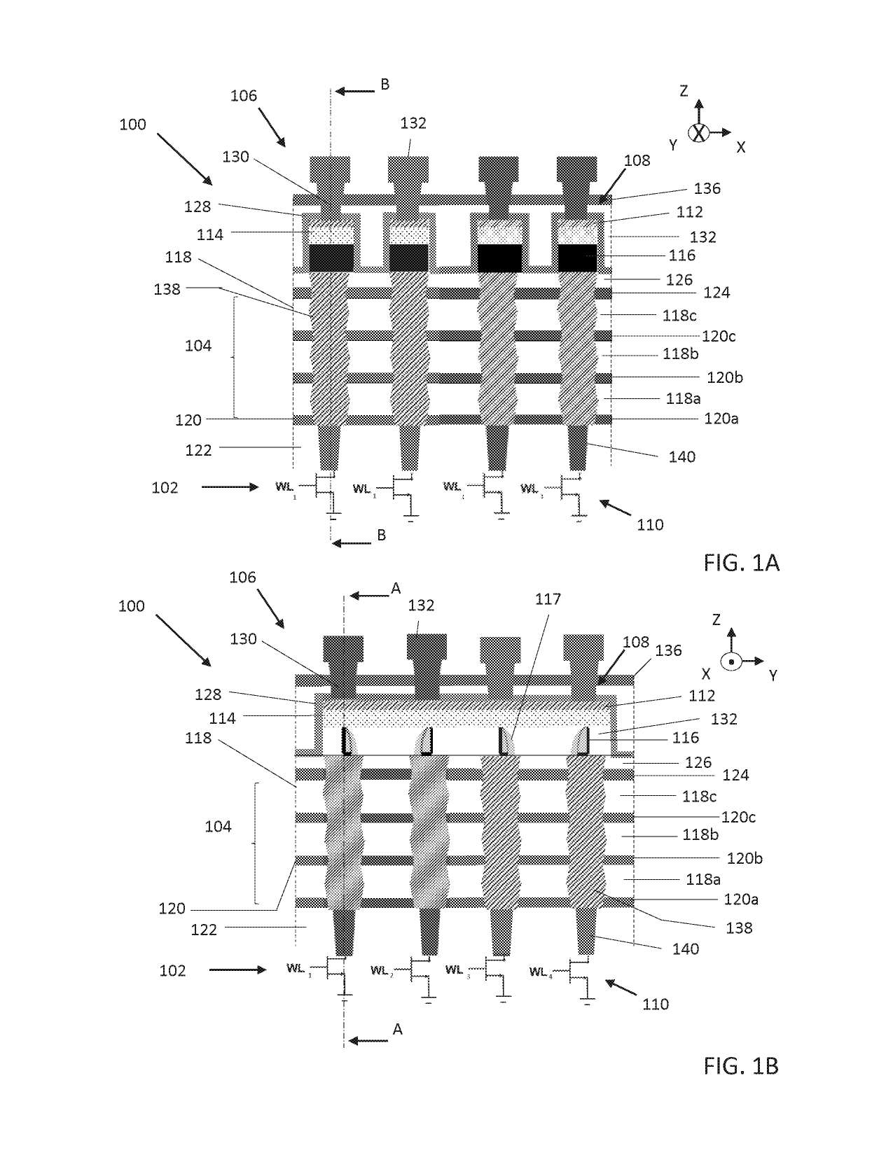

FIG. 1A is a simplified cross-section view of an example of a memory circuit 100. FIG. 1B is another schematic and partial view of the memory circuit 100 illustrated in FIG. 1A, FIG. 1A being a view along the cross-section plane AA of FIG. 1B and FIG. 1B being a view along the cross-section plane BB of FIG. 1A.

More particularly, FIG. 1A and FIG. 1B illustrate a portion of a memory circuit 100 of an electronic chip 300. As an example, electronic chip 300 comprises, in a portion not shown, a logic circuit adjacent to the memory circuit 100. The logic and memory circuits are, for example, manufactured simultaneously inside and on top of a same semiconductor substrate.

The memory circuit 100 is illustrated in a direct 3D coordinate system XYZ, FIG. 1A corresponding to a view in a plane XZ of the system and FIG. 1B corresponding each to a view in a plane YZ of the system.

The memory circuit 100 comprises a semiconductor substrate 102.

As an example, substrate 102 is made of silicon.

The memory circuit 100 further comprises an interconnection stack 104, arranged on top of the semiconductor substrate 102.

Interconnection stack 104 is, for example, formed by a succession of levels, each level comprising a first insulating layer 118 and a second insulating layer 120.

Interconnection stack 104 is for example formed on top of an insulating layer 122. Insulating layer 122 has, for example, a thickness in the range from 50 nm to 250 nm, for example in the range from 80 nm to 150 nm.

Interconnection stack 104 is, for example, formed on the upper surface of insulating layer 122 and covers, for example, the entire surface of insulating layer 122. Interconnection stack 104 comprises, for example, an insulating layer 120a formed on top of and in contact with the upper surface of insulating layer 122. Interconnection stack 104 further comprises an insulating layer 118a formed on insulating layer 120a. Insulating layer 118a is, for example, formed over the entire surface of insulating layer 120a. As an example, insulating layer 118a is in contact, by its lower surface, with the upper surface of insulating layer 120a. Layers 120a and 118a form a level of the interconnection stack.

Interconnection stack 104 may further comprise additional levels formed on top of and in contact with insulating layer 118a. In FIGS. 1A and 1B, interconnection stack 104 comprises two additional levels, for example respectively formed by layers 118b and 120b and layers 118c and 120c. In practice, the number of levels in interconnection stack 104 may be different from three, for example greater than or equal to one.

As an example, interconnection stack 104 has a thickness in the range from 100 nm to 600 nm, for example in the range from 200 nm to 500 nm, for example in the order of 300 nm.

For example, the thickness of each level formed by insulating layers 120 and 118 is in the range from 80 nm to 120 nm, for example in the order of 100 nm.

Interconnection stack 104 is, for example, topped with an insulating layer 124. Insulating layer 124 is, for example, formed on top of and in contact with interconnection stack 104 and more particularly on top of and in contact with insulating layer 118c. Insulating layer 124 extends, for example, over the entire surface of interconnection stack 104.

As an example, insulating layers 122 and 118 are made of a material having a low dielectric constant, for example made of a material having a dielectric constant (corresponding to the permittivity of said material relative to the permittivity of vacuum) smaller than 5, for example smaller than 4. Insulating layers 118 and 122 are ,for example, made of SiOC, porous SiOC, SiOCH, or porous SiOCH. As an example, insulating layers 120 and 124 are made of silicon carbonitride (SiCN), silicon nitride, SiCH, SiNHC or porous SiCN. As an example, insulating layers 120 and 124 have a thickness in the range from 2 nm to 50 nm, for example in the range from 10 nm to 20 nm, for example in the order of 15 nm. As an example, insulating layers 118 have a thickness in the range from 30 nm to 110 nm, for example in the range from 50 nm to 100 nm, for example in the order of 85 nm.

Insulating layer 124 is, for example, topped with an insulating layer 126. Insulating layer 126 is, for example, made of a material having a low dielectric constant, or of silicon dioxide (SiO₂). As an example, insulating layer 126 is formed on top of and in contact with the upper surface of insulating layer 124. As an example, insulating layer 126 has a thickness in the range from 10 nm to 50 nm, for example in the range from 20 nm to 30 nm.

Moreover, the memory circuit 100 comprises a plurality of memory cells 106.

Each memory cells 106 comprises a memory element 108 arranged above the interconnection stack 104 and a fin field-effect selection transistor (referred to in the art as a “Fin-FET”) 110, formed in the semiconductor substrate 102.

In this example, interconnection stack 104 is formed between substrate 102 and memory elements 108. Memory elements 108 are, for example, organized, in top view, in an array of rows and columns. The array or rows and columns is associated with word lines and bit lines, each memory element 108 being located at the intersection of a bit line and a word line. As an example, the memory elements 108 illustrated in FIG. 1A are memory elements 108 of a same word line, while the memory cells illustrated in FIG. 1B are memory cells of a same bit line. In FIG. 1A, only four bit lines are shown and in FIG. 1B, only four word lines are shown. However, in practice, a memory circuit may comprise a number of bit lines and of word lines respectively different from four, for example greater than four.

Each memory element 108 comprises a second electrode, for example a resistor 116, or resistive element having a fixed resistance value, and a first electrode 112.

The electronic cell 100 further comprises an intermediate layer 114 comprising, for example consisting of, an ovonic threshold switch (OTS) material, the resistor 116 being connected to the intermediate layer 114. The intermediate layer 114, or OTS layer, is located between the resistor 116 and the first electrode 112. The OTS layer 114 is, for example, in contact, for example in direct contact, with the resistor 116.

Exemplarily in FIGS. 1A and 1B, the first electrode 112 forms an electrode of the memory element 108 while the resistor 116 forms another electrode of the memory element 108.

Memory elements 108 are, in this embodiment, are formed on the upper surface of insulating layer 126.

The OTS layer 114 is, for example, made a chalcogenide material, e.g., germanium. Alternatively, the OTS layer 114 is made of any other chalcogenide material, for example selected from the following group: germanium (Ge), tellurium (Te), selenium (Se), arsenic (As) or any combination or alloy of these materials. The OTS layer may, for example, also be doped, preferably with antimony (Sb), indium (In) or silicon (Si).

Further examples of ovonic materials adapted to form OTS layer 114 can be found in United States Patent No. 8,148,707 (corresponding to European Patent No. 2204851), the content of which is hereby incorporated by reference to the extent authorized by law.

Typically, the chalcogenide material of the OTS layer 114 is not a phase-change-material, i.e., the OTS layer is made of an amorphous material regardless of the energy applied. In other words, the chalcogenide material of the OTS layer 114 is always an amorphous material. This means that the intermediate layer 114 is free of any phase change material.

The OTS layer 114 has, for example, a thickness greater than or equal to 2 nm, preferably greater than or equal to 5 nm, and/or less than or equal to 15 nm, preferably less than or equal to 10 nm. Exemplarily, the OTS layer 114 has a thickness of 8 nm.

The resistor 116 has, for example, an L-shaped cross-section, i.e., the resistor 116 has a horizontal portion and a vertical portion. The resistor 116 is, for example, surrounded by an insulating layer, not shown. The thickness of this insulating layer is such that the upper surface of the vertical portion of the resistor 116 is coplanar with the upper surface of the insulating layer. The resistor 116 has an L-shaped cross-section, but the shape of the resistor 116 can easily be configured with a squared-shaped cross-section or any other shapes (not shown). As an example, the resistor is in contact with the OTS layer, by its horizontal portion.

As an example, the resistor 116 is separated from the OTS layer 114 by a metallic layer, not shown, extending, for example, on the entire surface of the OTS layer.

The first electrode 112 and the resistor 116 are, for example, made of the same metallic material, e.g., tungsten. Alternatively, the first electrode 112 and the resistor 116 can be made of two different metallic materials. For example, the resistor and/or the first electrode is/are made of a (refractory) metallic material, preferably selected from the group: carbon (C), carbon nitride ((CN)n), titanium (Ti), titanium nitride (TiN), titanium silicon nitride (TiSiN), tungsten (W), tungsten nitride (W₂N, WN, WN₂), tungsten carbon nitride, tungsten silicon nitride, tantalum (Ta), tantalum nitride (TaN), tantalum silicon nitride, tantalum tungsten, or any combination or alloy of these materials. As an example, the memory elements 108 comprise a spacer 117 covering the horizontal portion of each resistor 116. The spacers 117 are made of an insulating material.

In one alternative embodiment (not shown) the second electrode is a conductive (e.g., metallic) layer entirely covering the bottom surface of the OTS layer 114. In this embodiment, the second electrode has substantially the same structure as the first electrode. In other words, the second electrode is formed by the above-described metallic layer that separates the resistor 116 from the OTS layer 114, with the resistor 116 that is absent. The second electrode may be made of the same material as the first electrode 112. For example, the first and second electrodes may be made of a refractory metallic material such as carbon (C), carbon nitride ((CN)n), titanium (Ti), titanium nitride (TiN), titanium silicon nitride (TiSiN), tungsten (W), tungsten nitride (W₂N, WN, WN₂), tungsten carbon nitride, tungsten silicon nitride, tantalum (Ta), tantalum nitride (TaN), tantalum silicon nitride, tantalum tungsten, or any combination or alloy of these materials.

As an example, the memory elements 108 of a same bit line are topped with a first electrode 112. In other words, the first electrode 112 of the memory elements 108 of a same bit line are interconnected.

Each memory element 108 is, for example, covered with an insulating layer 128 protecting layer 114 of OTS materials from oxidation. Insulating layer 128 is made of a nitride, for example made of silicon nitride. Each memory element 108 is further topped with a metal contact 130 extending, for example, over metallization 112. Metal contacts 130 are, for example, made of copper.

The OTS layer 114 and the first electrode 112 of each memory element 108 are separated from respective OTS layers 114 and first electrodes 112 of the adjacent elements 108, from memory elements connected to different word lines, by an insulating layer 132. In another embodiment not shown, the separation occurs also between memory elements connected to different bit lines. In other words, the OTS layer 114 is “fully confined”. The OTS layer 114 and the first electrode 112 have, for example, a parallelepipedal shape having, for example, for both layers the same width and the same length.

Insulating layer 132 is, for example, made of a material having a low dielectric constant. As a variant, layer 132 is made of an oxide, for example, of silicon dioxide. As an example, the layer 132 is made of the same material as the spacers 117.

Each contact 130 preferably extends from the upper surface of metal element 112 to the upper surface of layer 132. Thus, each contact 130 crosses layer 128 to reach the metal element 112 of the corresponding cell. The upper surface of each element 130 is thus coplanar with the upper surface of layer 132.

Similar to what has been described for electrodes 112, the contacts 130 of the memory elements 108 of the same bit line are interconnected. Contacts 130 are, for example, coupled to one another in layer 132. Alternatively, each contact 130 is coupled to a set of conductive vias and of conductive tracks 134 located in a level of an interconnection network resting on layer 132.

Layer 132 is, for example, topped with a conductive layer 136. Conductive layer 136 is, for example, made of silicon nitride or silicon carbonitride. Layer 136 and layers not shown, are for example, comprised in the interconnection network resting on layer 132.

Each memory element 108 is electrically connected to the selection transistor 110 with which it is associated via a conductive via 138 extending through the entire thickness of interconnection stack 104. As an example, via 138 extends through all the insulating layers 118 and 120 of interconnection stack 104.

As an example, via 138 is in contact, by its upper surface, with the lower surface of the resistor 116 of memory element 108. Via 138 is, for example, in contact, by its lower surface, with another conductive via 140.

As an example, for each memory element 108, the corresponding via 138 electrically couples the heating element 116 of the memory cell to the transistor 110.

Conductive via 138 is, for example, made of a metallic material. Conductive via 138 is, for example, made of tungsten. As a variant, conductive via 138 is made of cobalt or of copper. Conductive via 138 has, for example, a width, taken in the plane of FIG. 1A and in the plane of FIG. 1B, in the range from 40 nm to 100 nm, for example in the order of 70 nm.

Conductive vias 138 are formed, for example, after the interconnection stack 104 formation and after the layers 124 and 126 formation, in a single step. Consequently, each conductive via 138 is in a single piece (i.e., the via 138 in an integral, unitary, body of conductive metal material). Indeed, at the end of the formation of the interconnection stack 104 opening are, for example, formed in the interconnection stack 104. As an example, openings emerge onto the upper surfaces of vias 140. The openings extend, for example, the full height of the interconnect stack 104. Openings are, for example, formed by etching, for example by dry etching. As an example, openings are etched through an etch mask. As an example, the openings are created by a single etching step through all the interconnection stack 104. The etch mask is, for example, deposited and structured prior to the step of etching of openings by photolithography. As an example, openings may not have perfectly rectilinear and vertical sides. Indeed, layers 118 and 120 are of different natures and thus do not have the same etching speed. It can thus be provided for openings to be wider in layers 118. The openings creation is followed by a step of filling the openings with the material of via 138, for example a single and continuous in time, filling step.

Further conductive via 140 (in the following, conductive vias 140 for easiness of explanation) for example crosses insulating layer 122. Conductive via 140 is flush, for example, by its lower surface, with the lower surface of insulating layer 122, and by its upper surface, with the upper surface of insulating layer 122. Conductive via 140 is, for example, in contact, by its upper surface, with the lower surface of conductive via 138. Conductive via 140 is, for example, made of a metallic material, for example made of tungsten.

Exemplarily each transistor 110 is connected to the resistor 116 on opposite side with respect to the intermediate layer 114. It will be noted that in this way it is possible to reduce the operating voltage of the overall electronic cell with advantages in terms of power consumption. Moreover, it will be noted that the transistor can act as selector element, thus allowing the OTS layer 114 to only perform the memory function. In this way it is possible to use an OTS layer with relatively low thickness.

Alternatively, the transistor 110 may be connected to the first electrode 112 on opposite side with respect to the intermediate layer 114.

For example, the transistor 110 is a n-MOS transistor (for example implemented as a FinFET). It will be noted that a n-MOS FinFET transistor can be easily driven, thus simplifying the overall operation of the memory circuit. In another example, the transistor 110 is a p-MOS transistor (for example implemented as a FinFET). It will be noted that the FinFET transistors have high performances, low dimensions and/or high frequency range of operations. This favors the use of the electronic cell for embedded applications, e.g., for automotive applications.

As can be schematically seen in FIGS. 1A and 1B, each transistor 110 is connected by its gate to a word line (WL).

Although this is not illustrated in FIGS. 1A and 1B, the gates are coupled to metal contacts, for example formed on top of the memory circuit 100. Contacts correspond, for example, to conductive tracks of the interconnection network extending over layer 132.

As an example, each gate is coupled to such metal contact by the succession of vias and of conductive (not shown) tracks successively extending through insulating layer 122, interconnection stack 104, conductive layer 124, insulating layer 126, layer 128, insulating layer 132, and layer 136. As an example, each gate is topped with a conductive via extending through insulating layer 122, similarly to via 140.

As an example, the memory elements 108 of a same word line are connected to the same contact.

In this example, the transistor 110 has, a first conduction node, for example its drain, connected to the resistor 116 and more specifically connected to the horizontal part of the resistor 116. In this example, the transistor 110 has a second conduction node, for example its source connected to the ground.

The OTS layer 114 has the property to have a significant decrease of resistivity when the voltage applied between the electrode 112 and the resistor 116 exceeds a threshold voltage V_{TH}. This decrease (or increase) triggered by the voltage which is applied between the top and the bottom of the layer allows to consider the layer as forming a switch between an "off" state and an "on" state. If the voltage applied to OTS layer 114 is lower than the threshold V_{TH} of the OTS layer 114, then the OTS layer 114 remains in the "off" or highly resistive state. In such a state, only a leakage current flows through the memory cell 106. If a voltage higher than the threshold V_{TH} is applied, then the OTS layer 114 switches to the "on" state and operates in a relatively low resistive state. In the "on" state, a current flows through the memory cell 106. The threshold voltage V_{TH} of the OTS layer 114 is, for example, inclusively between 0,5 V to 5 V.

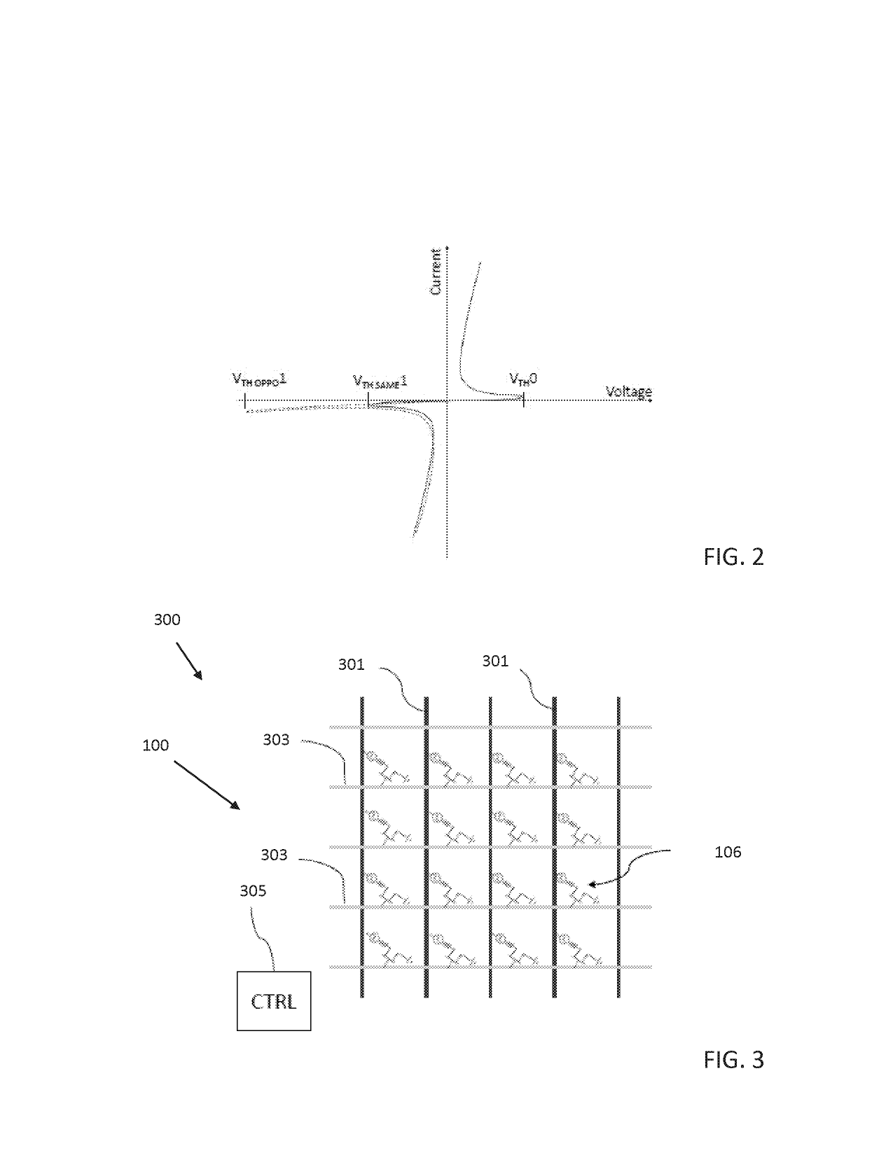

FIG. 2 is a graph illustrating the evolution of the current as a function of the voltage applied to the electrodes of the memory cell 106.

In a dual polarity operation, when the voltage applied to the memory cell 106 exceeds a first threshold voltage V_{TH}0 in a positive polarity or first polarity, the OTS layer 114 becomes conductive in an "on" state and is programmed as a "0" or in a first logic state and then becomes resistive again in an "off" state as the applied voltage decreases. Similarly, when the voltage applied to the memory cell exceeds in absolute value a threshold voltage V_{TH}1 in a negative polarity or second polarity, the OTS layer 114 becomes conductive in an "on" state and is programmed as a "1" or in a second logic state and then it becomes resistive again in an "off" state with the decrease of the applied voltage.

It will be noted that when a memory cell is programmed twice in a row (twice consecutively) as a "1", the threshold voltage V_{TH}1 is less important in absolute value, than when a memory cell is programmed as a "0" and then as a "1". In other words, if a same memory cell was programmed as a "1" and then it is reprogrammed as a "1" (with no programming as a "0" in-between), the threshold voltage V_{TH}1 is equal to V_{TH SAME}1 while if a same memory cell was programmed as a "0" and then it is programmed as a "1", the threshold voltage V_{TH}1 is equal to V_{TH OPPO}1 which is greater, in absolute value than V_{TH SAME}1. As an example, the voltage V_{TH SAME}1 is approximately equal, in absolute value, to the voltage V_{TH}0.

To take advantage of this memory effect, it is proposed to read the memory cells 106, during a reading phase, with a voltage V_{READ} which corresponds to a negative voltage whose value is comprised between V_{TH SAME}1 and V_{TH OPPO}1. With such a read voltage, if the measurement of the current flowing in the memory cell determines that the OTS layer 114 is conductive, it is because the threshold voltage V_{TH}1 corresponded to V_{TH SAME}1 which was exceeded, and that the memory cell had been programmed just before as a "1". Conversely, if the measurement of the current flowing in the memory cell determines that the OTS layer 114 is resistive, this means that the threshold voltage V_{TH}1 corresponded to V_{TH OPPO}1 which was not exceeded, and that the memory cell had been programmed just before as a "0".

It should be noted that a memory cell reading does not overwrite the programming since reading a programming as a "1" consists in reprogramming as a "1" and reading a programming as a "0" consists in not reprogramming the memory cell.

FIG. 3 illustrates a simplified schematic view of an electronic chip 300 comprising a memory circuit 100. The memory circuit 100 comprises, for example, an array of memory cells 106. The array of cells 106 exemplarily comprises a plurality of memory cells 106 as illustrated in FIGS. 1A and 1B. The memory circuit 100 comprises moreover, a control circuit 305 (CTRL), associated with the memory cells, and configured to apply, on each memory cell, a voltage between the two electrodes and more precisely between the resistor 116 and the first electrode 112.

The memory cells 106 are, in FIG. 3, positioned between a plurality of bit lines 301 and word lines 303. In FIG. 3, bit lines 301 are illustrated with vertical lines and word lines 303 are illustrated with horizontal lines.

Exemplarily, the control circuit 305 comprises (not shown) for each pair of bit line 301 and word line 303 a respective inverter (i.e., one inverter connected to the bit line of the pair and one further inverter connected to the word line of the pair). Preferably each inverter comprises a respective p-MOS transistor and a respective n-MOS transistor connected in series. In this way the control circuit is structurally simple and/or has relatively high performances.

Preferably the control circuit 305 is structured and configured to apply, between the first electrode 112 and the resistor 116, a read voltage impulse (of the first or the second polarity) having a voltage value between the first and second voltage threshold to determine a current logic state of the electronic cell.

Exemplarily, each memory cell 106 is connected to a bit line 301, by its first electrode 112 and is connected to a word line 303 by the gate of its transistor 110.

To be programmed, the memory cell 106 must have a non-zero voltage across it. For the programming of the memory cell 106 as a "0", its bit line 301 is put at a voltage corresponding to a value of +V and its word line 303 is put at a voltage exemplarily corresponding to a value of 0 V so that the transistor 110 is turned on and the electronic cell considered sees a voltage of V. For the programming of the memory cell 106 as a "1", its bit line 301 is put at a voltage corresponding to a value of -V and its word line 303 is put at a voltage corresponding to a value exemplarily of 0 V so that the transistor 110 is turned on and the electronic cell considered sees a voltage of -V.

For one or the other of the programs, the other memory cells of the memory circuit have either their respective transistors 110 on and seeing a voltage of exemplarily 0 V, or they have their transistor 110 off. These memory cells are therefore not programmed.

As an example, the operating voltage is comprised between 4 V and 6 V.

In one embodiment the control circuit 305 comprises, for each pair of bit line 301 and word line 303, a respective inverter (i.e., one inverter connected to the bit line of the pair and one further inverter connected to the word line of the pair), for example comprising a p-MOS transistor and n-MOS transistor in series.

An advantage of the present embodiment is that it enables to relax metal level sizing constraints for memory cell integration, since the surface area of vias 138 can be smaller than the surface area of a track connecting the word lines at the surface of interconnection stack 104.

Another advantage of the present embodiment is that the forming of the memory elements 106 above interconnection level 104 enables to limit risks of contamination of the OTS layer 114 of the memory element generated by the forming of the interconnection stack 104 and of the various metal levels connecting the word lines.

Still another advantage of the present embodiment is that it is compatible with known methods and logic parts, the logic part not being impacted.

Various embodiments and variants have been described. Those skilled in the art will understand that certain features of these embodiments can be combined, and other variants will readily occur to those skilled in the art.

Although embodiments have been described in which the memory cell selection transistors are fin field-effect transistors, it can be envisaged that the transistors may be of another type, such as bipolar or MOS transistors.

Finally, the practical implementation of the embodiments and variants described herein is within the capabilities of those skilled in the art based on the functional description provided hereinabove.

1. An electronic chip including a memory circuit, comprising:
a semiconductor substrate;
an interconnection stack arranged on the semiconductor substrate; and
a plurality of memory cells, wherein each memory cell comprises a memory element arranged above the interconnection stack and a selection transistor formed in the semiconductor substrate and comprising a first conduction node;
wherein each memory element comprises a first electrode, an intermediate layer comprising an ovonic threshold switching material, and a second electrode connected to the intermediate layer on opposite side with respect to the first electrode;
wherein, in each memory cell, the first conduction node of the selection transistor is connected to the memory element via a respective conductive via extending through an entire thickness of the interconnection stack; and
wherein the memory circuit further comprises a control circuit structured and configured to apply, between the first electrode and the second electrode of each memory element, a first voltage impulse of a first polarity to set a first logic state of the memory element and a second voltage impulse of a second polarity, opposite the first polarity, to set a second logic state of the memory element.

2. The electronic chip according to claim 1, wherein the intermediate layer is made of a chalcogenide material and wherein the second electrode comprises a resistor electrically contacting the intermediate layer.

3. The electronic chip according to claim 1, wherein the memory cells are organized in an array of bit lines and word lines and wherein each memory cell is connected to a respective bit line by its first electrode and to a respective word line by its second electrode.

4. The electronic chip according to claim 3, wherein each transistor comprises a gate which is connected to a respective word line, and a second conduction node connected to ground.

5. The electronic chip according to claim 1, wherein the memory cells are free of any phase change material.

6. The electronic chip according to claim 1, wherein the conductive via is made of a metallic material.

7. The electronic chip according to claim 1, wherein the interconnection stack has a thickness in a range from 100 nm to 600 nm.

8. The electronic chip according to claim 1:
wherein the interconnection stack comprises a plurality of levels, each level comprising a first insulating layer and a second insulating layer; and
wherein the first insulating layer is made of a material selected from the group consisting of: SiOC, porous SiOC, SiOCH, or porous SiOCH, and has a thickness in the range from 30 nm to 110 nm; and
wherein the second insulating layer is made of a material selected from the group consisting of: silicon carbonitride, silicon nitride, SiCH, SiNHC, or porous SiCN and has a thickness in the range from 2 nm to 50 nm.

9. The electronic chip according to claim 1, comprising:
a third insulating layer interposed between the interconnection stack and the memory element, wherein the third insulating layer is made of a material selected from the group consisting of: silicon carbonitride, silicon nitride, SiCH, SiNHC, or porous SiCN and has a thickness in the range from 2 nm to 50 nm; and
a fourth insulating layer interposed between the third insulating layer and the memory element, and wherein the fourth insulating layer is made of SiO₂, and has a thickness in the range from 10 nm to 50 nm.

10. The electronic chip according to claim 1, wherein, for each memory element, the respective conductive via is in single piece forming an integral, unitary, conductive via body extending through the entire thickness of the interconnection stack.

11. The electronic chip according to claim 1, further comprising:
an additional insulating layer interposed between the semiconductor substrate and the interconnection stack; and
for each memory element, a respective further via extending through an entire thickness of the additional insulating layer and directly connecting the selection transistor to the respective conductive via.

12. The electronic chip according to claim 1, wherein the conductive via is directly connected to the second electrode of the memory element.

13. The electronic chip according to claim 1, wherein the selection transistor is a fin field-effect transistor.

14. A method of manufacturing an electronic chip including a memory circuit, comprising the following successive steps:
a) forming selection transistors, comprising a first conduction node, in a semiconductor substrate;
b) forming an interconnection stack arranged on the semiconductor substrate; and
c) forming a plurality of memory elements arranged above the interconnection stack, each memory element comprising a first electrode, an intermediate layer comprising an ovonic threshold switching material, and a second electrode connected to the intermediate layer on opposite side with respect to the first electrode;
wherein the first conduction node of the selection transistor of each memory cell is connected to the memory element via a respective conductive via extending through an entire thickness of the interconnection stack; and
d) forming a control circuit structured and configured to apply, between the first electrode and the second electrode of each memory element, a first voltage impulse of a first polarity to set a first logic state of the memory element and a second voltage impulse of a second polarity, opposite the first polarity, to set a second logic state of the memory element.

15. The method according to claim 14, further comprising, between steps b) and c), forming the conductive via.

16. The method according to claim 15, wherein forming the conductive via comprises:
etching the interconnection stack to form an opening extending therethrough; and filling said opening with a metallic material.

17. The method according to claim 14, wherein the selection transistor is a fin field-effect transistor.
